(19) United States
(12) Patent Application Publication
(10) Pub. No.: US 2026/0018483 A1
(43) Pub. Date: Jan. 15, 2026

(54) MICROELECTRONIC DEVICES INCLUDING HEAT SINKS, AND ASSOCIATED DEVICES AND METHODS

(71) Applicant: Micron Technology, Inc., Boise, ID (US)

(72) Inventors: James E. Davis, Meridian, ID (US); Shyam Surthi, Boise, ID (US); Kenneth W. Marr, Boise, ID (US); Yui Shimizu, Santa Clara, CA (US); Michael D. Chaine, Boise, ID (US)

(21) Appl. No.: 19/233,418

(22) Filed: Jun. 10, 2025

Related U.S. Application Data
(60) Provisional application No. 63/669,626, filed on Jul. 10, 2024.

(51) Int. Cl. H01L 23/367; H01L 23/00; H01L 23/373; H01L 25/18; H10B 80/00; H10D 80/30

(52) U.S. Cl. CPC H01L 23/3677; H01L 24/08; H01L 25/18; H10B 80/00; H10D 80/30; H01L 23/3736; H01L 24/80; H01L 2224/08145; H01L 2224/80895; H01L 2224/80896; H01L 2225/06589; H01L 2924/1431

(57) ABSTRACT

A microelectronic device includes a control logic structure including a high-power component. The microelectronic device also includes a memory array structure vertically offset from and attached to the control logic structure, the memory array structure comprising an array of memory cells. The microelectronic device further includes a heat sink structure vertically underlying and horizontally overlapping the high-power component, the heat sink structure comprising a material having higher thermal conductivity than semiconductor material of the control logic structure.

### CROSS-REFERENCE TO RELATED APPLICATIONS

This application claims the benefit under 35 U.S.C. § 119 (e) of U.S. Provisional Patent Application Ser. No. 63/669,626, filed Jul. 10, 2024, the disclosure of which is hereby incorporated herein in its entirety by this reference.

### TECHNICAL FIELD

Embodiments of the disclosure generally relate to microelectronic devices. In particular, embodiments of the disclosure relate to microelectronic devices including heat sinks, and associated devices and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified, easier and less expensive to fabricate designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices) and volatile memory devices (e.g., dynamic random access memory (DRAM) devices).

Control logic devices within a base control logic structure underlying a memory array of a memory device have been used to control operations on the memory cells of the memory device. Control logic devices of the base control logic structure can be provided in electrical communication with conductive lines (e.g., digit lines, word lines) coupled to the memory cells by way of routing and contact structures. Unfortunately, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of a memory device, and/or improvements in the performance (e.g., faster memory cell ON/OFF speed, lower threshold switching voltage requirements, faster data transfer rates, lower power consumption) of the memory device.

### BRIEF DESCRIPTION OF THE DRAWINGS

FIG. 1 illustrates a simplified, partial vertical cross-sectional view of a microelectronic device, in accordance with embodiments of the disclosure;

FIG. 2 illustrates an enlarged, vertical cross-sectional view of a portion of the microelectronic device of FIG. 1;

FIGS. 3A-3C illustrate simplified, partial vertical cross-sectional views of different microelectronic devices, in accordance with additional embodiments of the disclosure;

FIGS. 4-5C illustrate simplified, partial vertical cross-sectional views of different microelectronic devices, in accordance with further embodiments of the disclosure;

FIG. 5D illustrates a simplified, partial top-down view of the microelectronic device of FIG. 5B;

FIGS. 6A and 6B illustrate simplified, partial vertical cross-sectional views of different microelectronic devices, in accordance with yet further embodiments of the disclosure;

FIG. 6C illustrates a simplified, partial top-down view of the microelectronic device of FIG. 6A;

FIGS. 7A-7F illustrate simplified, partial top-down views of different microelectronic devices, in accordance with embodiments of the disclosure; and

FIG. 8 is a schematic block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, “conductive material” means and includes thermally conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes thermally insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, each of a “semiconductor structure” and a “semiconductive structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

Control logic devices (e.g., complementary metal-oxide semiconductor (CMOS devices)) within a base control logic structure underlying a memory array structure of a memory device (e.g., DRAM device, a NAND device) may be used to control operations of the memory device. Processing conditions (e.g., temperatures, pressures, materials) conventionally employed for the formation of a conventional memory array structure over a conventional base control logic structure can limit the configurations and performance of the control logic devices within the base control logic structure and/or the configurations and performance of memory cells within the memory array structure. In addition, the quantities, dimensions, and arrangements of the different control logic devices employed within the base control logic structure can also undesirably impede reductions to the size of a memory device, and/or improvements in the performance of the memory device.

Bonding techniques, such as wafer-to-wafer bonding may facilitate forming the control logic structure (including the control logic circuitry and devices thereof) separately from a memory array structure (including the arrays of memory cells thereof). Forming the control logic structure and the memory array structure separately may facilitate reductions in size and/or performance enhancements for a memory device subsequently formed using wafer-to-wafer bonding relative to conventional memory device configuration. After the control logic structure and the memory array structure are separately formed, they may be bonded to one another in a desired arrangement (e.g., a face-to-back (F2B) configuration, where a back of the control logic structure is bonded to a face of the memory array structure; a face-to-face (F2F) configuration, a back-to-face (B2F) configuration; a back-to-back (B2B) configuration). For example, the control logic structure may be bonded to the memory array structure through wafer-to-wafer bonding by at least forming dielectric-to-dielectric (e.g., oxide-to-oxide) bonds between the dielectric material (e.g., dielectric oxide material) of the control logic structure and additional dielectric material (e.g., additional dielectric oxide material) of the memory array structure. For example, oxide-to-oxide bonds may be formed between the control logic structure and the memory array structure to form a relatively larger assembly by bringing the dielectric oxide materials of the control logic structure and the memory array structure in physical contact and applying a temperature greater than or equal to about 400° C. (e.g., within a range of from about 400° C. to about 800° C., greater than about 800° C.) to form the oxide-to-oxide bonds. In some embodiments, the dielectric oxide materials are exposed to at least one temperature greater than about 800° C. to form the oxide-to-oxide bonds between the control logic structure and the memory array structure.

The reductions in size facilitated by the aforementioned wafer-on-wafer bonding techniques may result in a reduction in the ability of the resulting microelectronic device (e.g., memory device) to dissipate heat. For example, base semiconductor materials (e.g., silicon) of the control logic structure and/or the memory array structure operatively associated therewith may act as a heat sink for some control logic devices of the control logic structure. Wafer-on-wafer may permit reducing a vertical thickness of such one or more base semiconductor materials, but may correspondingly result in a reduction of the heat sink functionality facilitated by the base semiconductor materials. Thus, absent the configuration of the disclosure described hereinbelow, relatively high powered circuits and devices of a control logic structure, such as electrostatic discharge (ESD) protection circuitry and devices, may suffer from insufficient heat dissipation. Such issues with heat dissipation may otherwise result in less desirable (e.g., relatively larger) microelectronic device dimensions, and/or a reduction in performance (e.g., speed, memory cell ON/OFF speed, threshold switching voltage, data transfer rates, power consumption) of the microelectronic device.

Embodiments of the disclosure include heat sink structures embedded in one or more of the control logic structure and the memory array structure to facilitate the dissipation of heat from control logic circuitry and devices (e.g., relatively high power devices, such as ESD devices) of the control logic structure. The heat sink structures may facilitate reductions in a size of a microelectronic device (e.g., memory devices) including the control logic structure and the memory array structure, as compared to conventional microelectronic device configurations, without effectuating undesirable overheating the microelectronic device during use and operation of the microelectronic device.

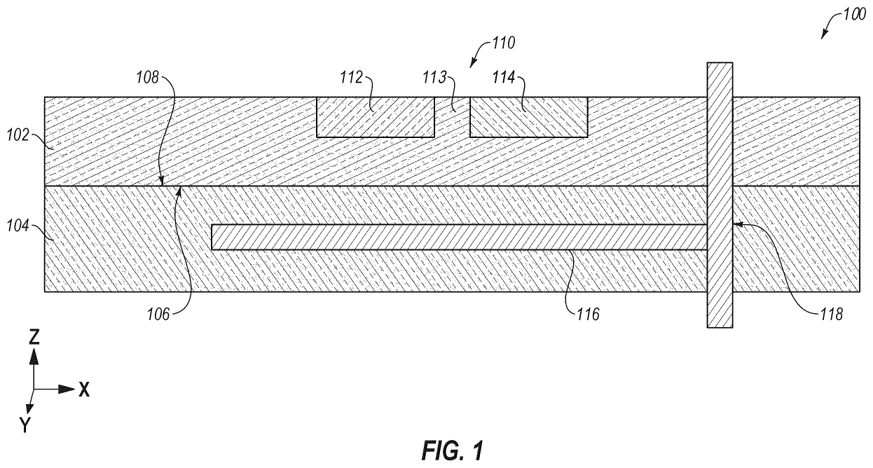

FIG. 1 illustrates a simplified, partial vertical cross-sectional view of a microelectronic device 100 (e.g., memory device), in accordance with embodiments of the disclosure. The microelectronic device 100 including a control logic structure 102 (e.g., a control logic die) is bonded to a memory array structure 104 (e.g., a memory array die). A back side 106 of the control logic structure 102 is bonded (e.g., dielectric-to-dielectric bonded) to a face 108 of the memory array structure 104 at an interface. The control logic structure 102 includes a high-power component 110. The high-power component 110 may be a device or circuit configured to receive relatively high voltages and/or to handle relatively high currents. By way of non-limiting example, the high-power component 110 may be an electrostatic discharge (ESD) protection device (e.g., an ESD diode, an ESD suppressor), transistor logic circuits, charge pumps, regulators, on-die termination (ODT) devices, amplifier circuitry, or a resistor.

In the embodiment illustrated in FIG. 1, the high-power component 110 is an ESD diode including electrodes 112, 114. One of the electrodes 112, 114 may be an anode (e.g., a positive electrode) and the other of the electrodes 112, 114 may be a cathode (e.g., a negative electrode). The electrodes 112, 114 are separated from one another by semiconductor material 113 (e.g., silicon) of the control logic structure 102 to form the ESD diode. The semiconductor material 113 interposed between the electrodes 112, 114 may permit electrical current to pass (e.g., flow) from the electrode 112 to the electrode 114, or vice versa, when a voltage between the electrode 112 and the electrode 114 is above a threshold value to discharge electrostatic energy and substantially prevent damage to other components of the microelectronic device 100.

Passing electrical current between the electrode 112 and the electrode 114 may generate heat at least due to the resistance of the semiconductor material 113 interposed between the electrode 112 and the electrode 114. The semiconductor material 113, as a whole of the control logic structure 102, may dissipate thermal energy (e.g., heat) generated by the current passing between the electrode 112 and the electrode 114. However, as a vertical thickness (e.g., in the Z-direction) of the semiconductor material 113 is decreased, the capability of the semiconductor material 113, as a whole, to dissipate generated thermal energy is correspondingly reduced. Accordingly, in accordance with embodiments of the disclosure, a heat sink structure 116 is provided to vertically underlie (e.g., in the Z-direction) and horizontally overlap (e.g., in the X-direction, in the Y-direction) the high-power component 110 of the control logic structure 102. The heat sink structure 116 may be configured to dissipate thermal energy generated by the current passing between the electrode 112 and the electrode 114 that is not dissipated by the semiconductor material 113 of the control logic structure 102. The heat sink structure 116 may be formed of and include material having relatively high thermal conductivity, such as one more of tungsten, aluminum, and copper.

In some embodiments, the heat sink structure 116 is positioned in an upper portion of the memory array structure 104 near the face 108 of the memory array structure 104, as illustrated in FIG. 1. In other embodiments, the heat sink structure 116 is positioned in a lower portion of the control logic structure 102 near the back side 106 of the control logic structure 102, as discussed in further detail below. The heat sink structure 116 may be arranged to horizontally extend (e.g., in the X-direction, in the Y-direction) beyond a horizontal area of the high-power component 110. For example, the heat sink structure 116 may horizontally span a distance, in the X-direction, which is greater than a width, in the X-direction, of the high-power component 110. The high-power component 110 may be positioned in the control logic structure 102 in a region that is not positioned over auxiliary contact structures of the memory array structure 104, such that the heat sink structure 116 may extend through the memory array structure 104 without contacting the auxiliary contact structures of the memory array structure 104.

In some embodiments, the heat sink structure 116 serves as a ground bus within the microelectronic device 100. For example, the heat sink structure 116 may be coupled to one or more contact structures 118 that may be connected to a ground for the microelectronic device 100. In other embodiments, the heat sink structure 116 and the contact structures 118 combine to form a larger heat sink for the microelectronic device 100 without being electrically connected to other features of the microelectronic device 100. For example, thermal energy generated by the current passing between the electrode 112 and the electrode 114 may be transferred vertically (e.g., in a Z-direction) to the heat sink structure 116 through the control logic structure 102 and the memory array structure 104, and the heat may also be transferred horizontally (e.g., in the X-direction) to the contact structure 118 through the control logic structure 102.

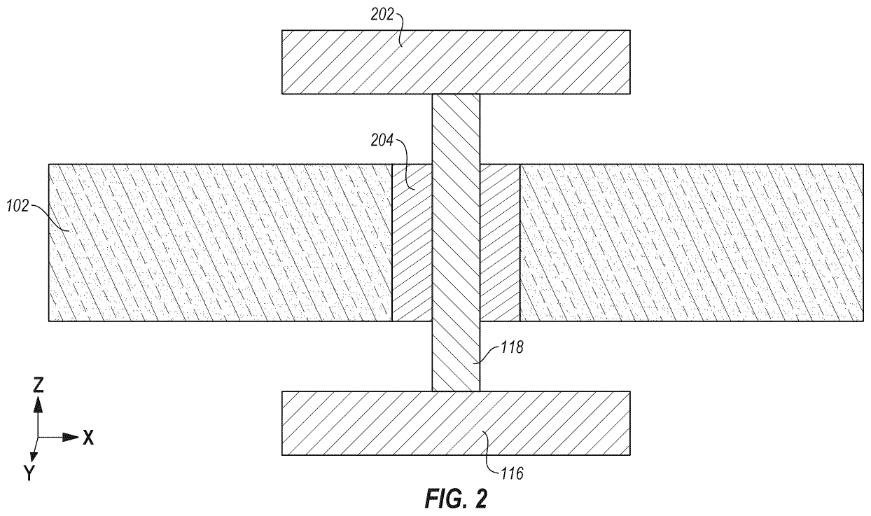

FIG. 2 illustrates an enlarged, vertical cross-sectional view of the control logic structure 102 and the interface between the contact structure 118 and the heat sink structure 116. As illustrated in FIG. 2, the contact structure 118 provides a connection between the heat sink structure 116 and a secondary structure 202. The contact structure 118 and the secondary structure 202 may each be formed from a material having a high thermal conductivity, such as one or more of tungsten, aluminum, and copper. Thus, the contact structure 118 may provide a thermal connection between the heat sink structure 116 and the secondary structure 202. In some embodiments, the contact structure 118 is also configured to provide an electrical connection between the heat sink structure 116 and the secondary structure 202, such as when the heat sink structure 116 and the contact structure 118 are operating as a ground bus.

In some embodiments, the secondary structure 202 is an electrical contact, such as a contact pad, a via, a post, a pin, or a solder bump. In other embodiments, the secondary structure 202 is a second heat sink structure. For example, multiple microelectronic devices 100 may be vertically stacked in the Z-direction and the heat sink structures 116 of the stacked microelectronic devices may be thermally connected to one another through the contact structure 118, such that the heat sink structure 116, the contact structure 118, and the secondary structure 202 combine to form a relatively larger heat sink structure having greater heat dissipation capabilities.

The control logic structure 102 may include an insulative structure 204 positioned between one or more additional materials (e.g., the semiconductor material 113) of the control logic structure 102 and the contact structure 118. The insulative structure 204 may be configured to substantially electrically isolate the contact structure 118 from the additional materials of control logic structure 102. For example, the insulative structure 204 may be formed of and include dielectric oxide materials, such as SiOₓ (e.g., SiO₂) or SiN_{y} (e.g., Si₃N₄).

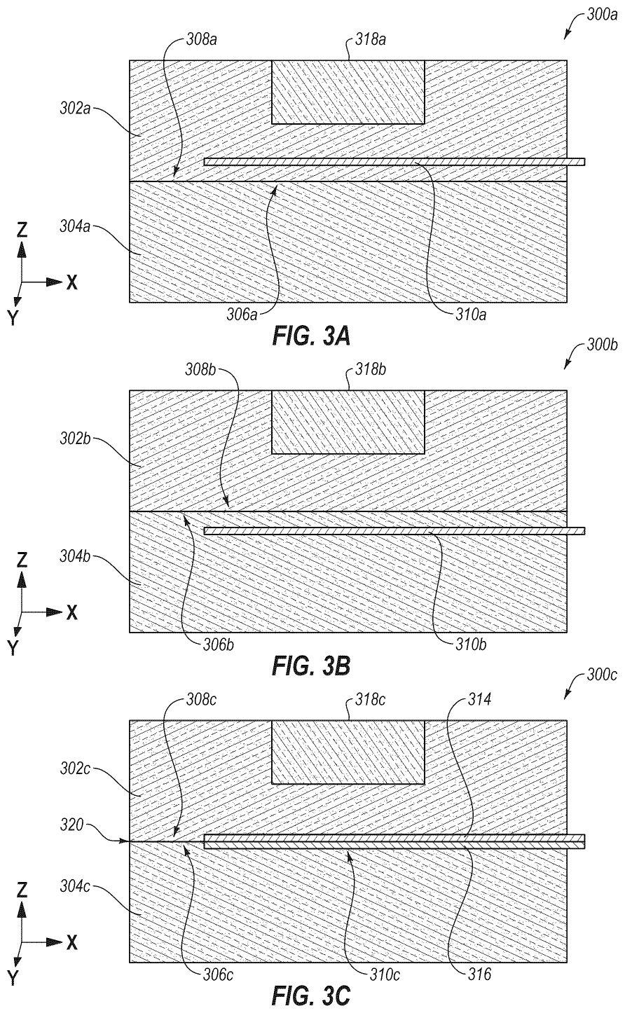

FIGS. 3A-3C illustrate simplified, partial vertical cross-sectional views of different microelectronic devices 300a (FIG. 3A), 300b (FIG. 3B), 300c (FIG. 3C) with heat sink structures 310a (FIG. 3A), 310b (FIG. 3B), 310c (FIG. 3C) positioned at different vertical arrangements (e.g., in the Z-direction) therein. With collective reference to FIGS. 3A-3C, in the microelectronic devices 300a, 300b, 300c the heat sink structure 310a, 310b, 310c vertically underlies and horizontally overlaps a high-power component 318a, 318b, 318c, respectively. The heat sink structures 310a, 310b, 310c also horizontally span (e.g., in the X-direction) a distance that is greater than a width (e.g., in the X-direction) of the high-power component 318a, 318b, 318c, respectively. A horizontal area of the high-power component 318a, 318b, 318c may at least partially (e.g., substantially) horizontally overlap (e.g., in the X-direction, in the Y-direction) a horizontal area of the heat sink structure 310a, 310b, 310c, respectively.

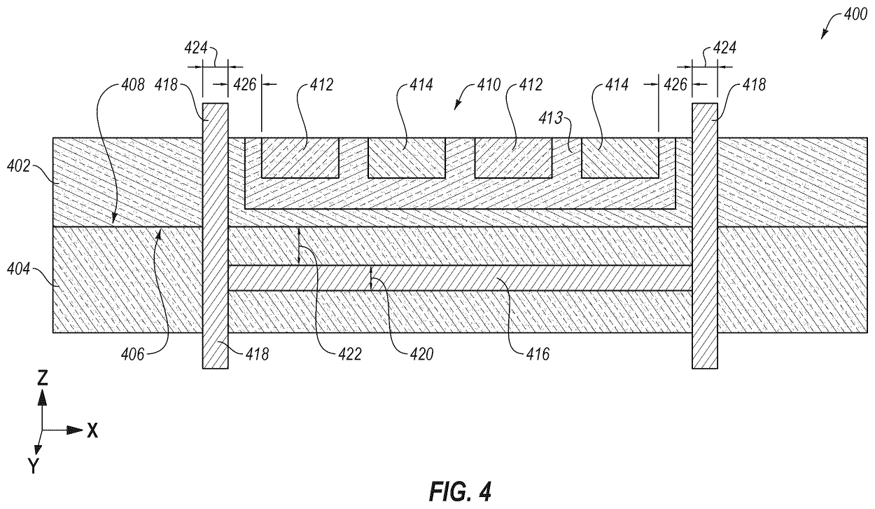

To avoid repetition, not all features (e.g., structures, materials, regions, devices) shown in FIGS. 3A-3C and subsequent FIGS. 4-7F are described in detail herein. Rather, unless described otherwise below, in FIGS. 3A-7F, a feature designated by a reference numeral that is a 100 increment of the reference numeral of a feature previously described with reference to one or more of FIGS. 1 and 2 will be understood to be substantially similar to the previously described feature.

In the embodiment illustrated in FIG. 3A, the heat sink structure 310a is positioned in the control logic structure 302a at a vertical position between the high-power component 318a and the back side 306a of the control logic structure 302a. The control logic structure 302a may be bonded to the memory array structure 304a through dielectric-to-dielectric bonds (e.g., oxide-to-oxide bonds) between dielectric material at the back side 306a of the control logic structure 302a and additional dielectric material at the face 308a of the memory array structure 304a.

To form the heat sink structure 310a, a material having high thermal conductivity may be formed and optionally patterned so as to be vertically offset from and horizontally overlap the high-power component 318a of the control logic structure 302a. Thereafter, dielectric material (e.g., silicon oxide, silicon nitride) may be formed on or over the heat sink structure 310a. The dielectric material may at least partially form the back side 306a of the control logic structure 302a.

The control logic structure 302a may then be bonded to the memory array structure 304a. For example, the back side 306a of the control logic structure 302a may be provided in physical contact with the face 308a of the memory array structure 304a, and then an annealing temperature greater than or equal to about 400° C. (e.g., within a range of from about 400° C. to about 800° C., greater than about 800° C.) may be applied to form the dielectric-to-dielectric bonds.

In the embodiment illustrated in FIG. 3B, the heat sink structure 310b is positioned at a vertical position in the memory array structure 304b vertically beneath the back side 306b of the control logic structure 302b. The dielectric material of the memory array structure 304b forms the face 308b of the memory array structure 304b. The control logic structure 302b is bonded to the memory array structure 304b through dielectric-to-dielectric bonds between the dielectric material at the face 308b of the memory array structure 304b and additional dielectric material at the back side 306b of the control logic structure 302b.

To form the heat sink structure 310b, a material having high thermal conductivity is formed at a horizontal location within the memory array structure 304b substantially corresponding to a horizontal location of the high-power component 318b of the control logic structure 302b. Thereafter, dielectric material (e.g., silicon oxide, silicon nitride) may be formed on or over the heat sink structure 310b. The dielectric material may at least partially form the face 308b of the memory array structure 304b.

The control logic structure 302b may then be bonded to the memory array structure 304b. For example, the back side 306b of the control logic structure 302b may be provided in physical contact with the face 308b of the memory array structure 304b, and then an annealing temperature greater than or equal to about 400° C. (e.g., within a range of from about 400° C. to about 800° C., greater than about 800° C.) may be applied to form the dielectric-to-dielectric bonds.

In the embodiment illustrated in FIG. 3C, the heat sink structure 310c is vertically positioned at an interface 320 between the control logic structure 302c and the memory array structure 304c vertically beneath the high-power component 318c of the control logic structure 302c. An upper portion 314 of the heat sink structure 310c forms a portion of the back side 306c of the control logic structure 302c, and a lower portion 316 of the heat sink structure 310c forms a portion of the face 308c of the memory array structure 304c. In the embodiment of FIG. 3C, the control logic structure 302c is bonded to the memory array structure 304c through combination of dielectric-to-dielectric bonds between the dielectric material at the face 308c of the memory array structure 304c and additional dielectric material at the back side 306c of the control logic structure 302c, and metal-to-metal bonds between the upper portion 314 and the lower portion 316 of the heat sink structure 310c.

To form the heat sink structure 310c, a material having high thermal conductivity is formed at a horizontal location within the memory array structure 304c substantially corresponding to a horizontal location of the high-power component 318c of the control logic structure 302c; and additional material having high thermal conductivity formed at a horizontal location within the control logic structure 302c substantially corresponding to the horizontal location of the high-power component 318c of the control logic structure 302c. Thereafter, the control logic structure 302c may then be bonded to the memory array structure 304c to form microelectronic device 300c and simultaneously form the heat sink structure 310c. For example, the back side 306c of the control logic structure 302c may be provided in physical contact with the face 308c of the memory array structure 304c, and then an annealing temperature greater than or equal to about 400° C. (e.g., within a range of from about 400° C. to about 800° C., greater than about 800° C.) may be applied to form the dielectric-to-dielectric bonds between the dielectric material at the face 308c of the memory array structure 304c and additional dielectric material at the back side 306c of the control logic structure 302c, while also forming metal-to-metal bonds between the additional material (corresponding to the upper portion 314) of the control logic structure 302c and the material (corresponding to the lower portion 316) of the memory array structure 304c to form the heat sink structure 310c.

FIG. 4 illustrates a simplified, partial vertical cross-sectional view of a microelectronic device 400, in accordance with embodiments of the disclosure. The microelectronic device 400 includes a heat sink structure 416 horizontally extending (e.g., in the X-direction) between two contact structures 418, such that the heat sink structure 416 and the contact structures 418 form a cup-like shape around a high-power component 410. In the embodiment illustrated in FIG. 4, the heat sink structure 416 is vertically positioned in the memory array structure 404 vertically below the control logic structure 402. Dielectric material of the memory array structure 404 at least partially forms the face 408 of the memory array structure 404. The control logic structure 402 is bonded to the memory array structure 404 through dielectric-to-dielectric bonds between the face 408 of the memory array structure 404 and the back side 406 of the control logic structure 402.

The heat sink structure 416 has a thickness 420 sufficient to dissipate a similar amount of heat to a control logic structure having a greater volume of semiconductor material. For example, the heat sink structure 416 may have a thickness in a range from about 5 nanometers (nm) to about 20 micrometers (μm), such as in a range from about 25 nm to about 10 μm or from about 2 μm to about 5 μm.

In the embodiment illustrated in FIG. 4, the heat sink structure 416 is positioned in the memory array structure 404 with a portion of semiconductor material of the memory array structure 404 between the heat sink structure 416 and the back side 406 of the control logic structure 402. The portion of the semiconductor material plus dielectric material of the memory array structure 404 defines a distance 422 between the heat sink structure 416 and the back side 406 of the control logic structure 402. As the distance 422 between the heat sink structure 416 and the back side 406 of the control logic structure 402 decreases, the heat transfer between the semiconductor material of the control logic structure 402 and the heat sink structure 416 may increase, which may improve the heat dissipation provided by the heat sink structure 416. The distance 422 between the heat sink structure 416 and the back side 406 of the control logic structure 402 may be less than about 5 μm, such as less than about 2 μm or less than about 1 μm. As discussed above, in some embodiments, the heat sink structure 416 is in direct contact with semiconductor material of the control logic structure 402, such that there is no distance 422 between the heat sink structure 416 and the control logic structure 402. For example, the heat sink structure 416 may be at least partially (e.g., substantially) disposed within the semiconductor material of the control logic structure 402, as illustrated in the microelectronic device 300a of FIG. 3A, or the heat sink structure 416 may form a portion of the back side 406 of the control logic structure 402, as illustrated in the microelectronic device 300c of FIG. 3C.

In the embodiment illustrated in FIG. 4, the heat sink structure 416 is coupled to the contact structures 418 extending vertically, in the Z-direction, through portions of the microelectronic device 400 horizontally neighboring, in the X-direction, sides of the high-power component 410. The contact structures 418 may be respectively formed of and include thermally conductive material similar to that of the heat sink structure 416, such that the heat sink structure 416 and the contact structures 418 effectively combine to form a relatively larger heat sink structure. The contact structures 418 may have a horizontal thickness 424 (e.g., in the X-direction) similar to the vertical thickness (e.g., in the Z-direction) of the heat sink structure 416. For example, the contact structures 418 may have a horizontal thickness 424 within a range from about 5 nm to about 20 micrometers (μm), such as from about 25 nm to about 10 μm, or from about 2 μm to about 5 μm. In some embodiments, the contact structures 418 respectively have a horizontal thickness 424 that is the same as the vertical thickness 420 of the heat sink structure 416. In other embodiments, one or more (e.g., each) of the contact structures 418 have a horizontal thickness 424 greater than the vertical thickness 420 of the heat sink structure 416.

The contact structures 418 may be respectively spaced a horizontal distance 426 from a nearest electrode 412, 414 of the high-power component 410 by semiconductor material of the control logic structure 402. For example, the semiconductor material of the control logic structure 402 may define a horizontal spacing distance within a range from about 0.1 μm to about 10 μm, such as within a range from about 1 μm to about 5 μm, or from about 1 μm to about 2 μm.

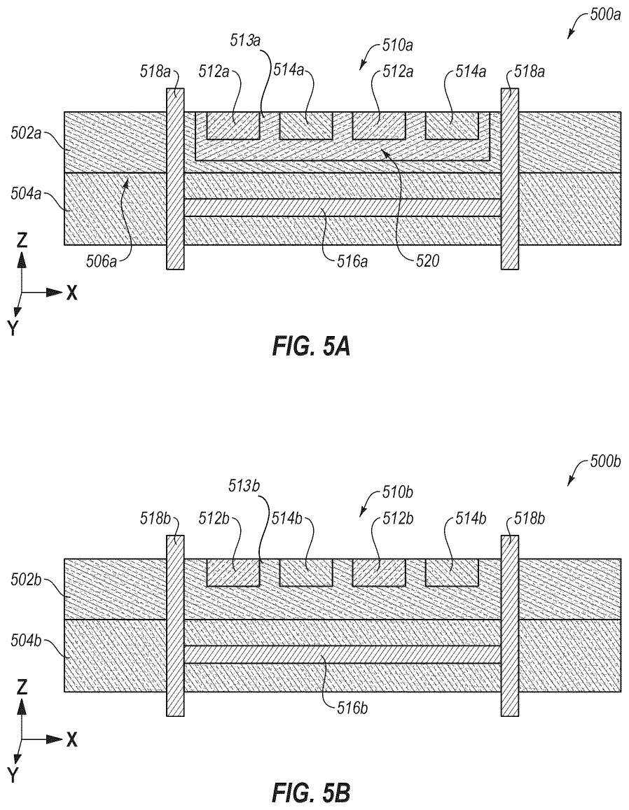

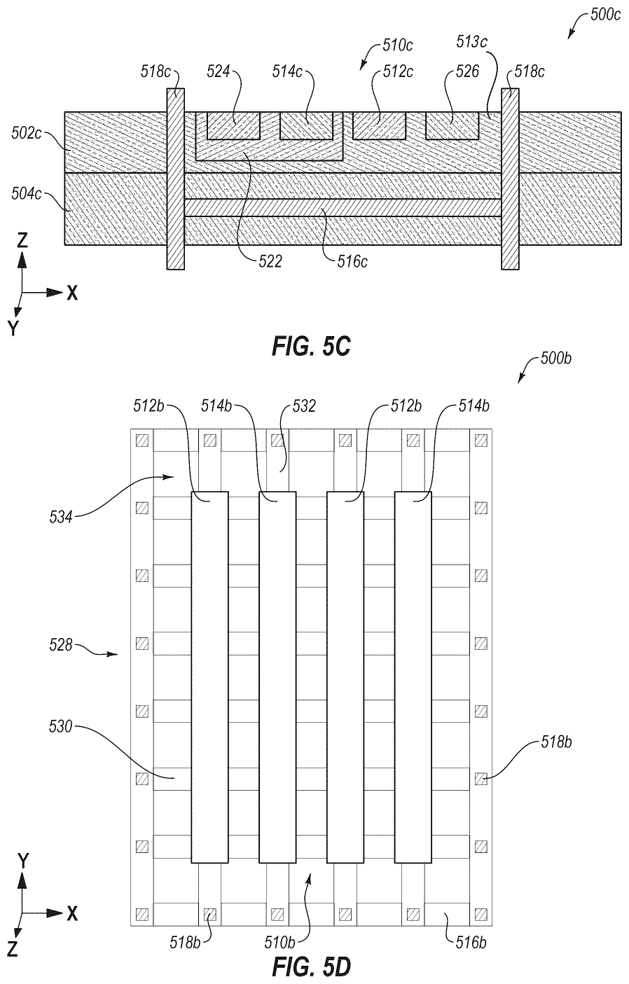

FIGS. 5A-5C illustrate simplified, partial vertical cross-sectional views of different microelectronic devices 500a (FIG. 5A), 500b (FIG. 5B), 500c (FIG. 5C), in accordance with embodiments of the disclosure. The microelectronic devices 500a (FIG. 5A), 500b (FIG. 5B), 500c (FIG. 5C) may have similar configurations to the microelectronic device 400 (FIG. 4), within different high-power components 510a (FIG. 5A), 510b (FIG. 5B), 510c (FIG. 5C) positioned within the cup-like structure formed by the combination of the heat sink structures 516a (FIG. 5A), 516b (FIG. 5B), 516c (FIG. 5C) and the contact structures 518a (FIG. 5A), 510b (FIG. 5B), 518c (FIG. 5C). In the embodiments illustrated in FIGS. 5A-5C, the high-power components 510a (FIG. 5A), 510b (FIG. 5B), 510c (FIG. 5C) may comprise different types of electrostatic discharge (ESD) diodes than one another. In the embodiment illustrated in FIG. 5A, the high-power component 510a includes an n-well ESD diode. In the embodiment illustrated in FIG. 5B, the high-power component 510b includes a p-well ESD diode. In the embodiment illustrated in FIG. 5C, the high-power component 510c includes an ESD silicon-controlled rectifier (SCR).

Referring to FIG. 5A, the microelectronic device 500a has a high-power component 510a including an n-well ESD diode. The high-power component 510a includes two types of electrodes 512a, 514a that are configured as anodes and cathodes. The electrodes 512a may be configured as anodes, and the electrodes 514a may be configured as cathodes. The electrodes 512a, 514a are substantially surrounded by an n-well 520 including n-type doped semiconductor material of the control logic structure 502a. The n-well 520 is interposed between the electrodes 512a, 514a and each of the heat sink structures 516a and the contact structures 518a. As illustrated in FIG. 5A, the contact structures 518a are positioned laterally outside the n-well 520 in the X-direction. Similarly, a horizontal area of the n-well 520 is within a horizontal area of the heat sink structure 516a.

As illustrated in FIG. 5A, the n-well 520 of the high-power component 510a is vertically positioned within the control logic structure 502a. Additional semiconductor material and dielectric material of the control logic structure 502a is positioned between the n-well 520 and the back side 506a of the control logic structure 502a. Additional semiconductor material of the control logic structure 502a also is positioned horizontally between the n-well 520 and the contact structures 518a horizontally neighboring the high-power component 510a.

In the embodiment illustrated in FIG. 5A, the heat sink structure 516a is vertically positioned within the memory array structure 504a. In other embodiments, the heat sink structure 516a is vertically positioned within the control logic structure 502a, or is vertically positioned within both the control logic structure 502a and the memory array structure 504a. A horizontal area of the high-power component 510a is at least partially (e.g., substantially) contained within a horizontal area of the heat sink structure 516a.

Referring next to FIG. 5B, the microelectronic device 500b has a high-power component 510b including a p-well ESD diode. The high-power component 510b includes two types of electrodes 512b, 514b that are configured as anodes and cathodes. In the embodiment illustrated in FIG. 5B, the electrodes 512b are configured as anodes, and the electrodes 514b are configured as cathodes.

The electrodes 512b, 514b are at least partially surrounded by semiconductor material of the control logic structure 502b. The semiconductor material of the control logic structure 502b is interposed between the electrodes 512b, 514b and each of the heat sink structures 516b and the contact structures 518b. Each of the electrodes 512b, 514b may be positioned within a horizonal area of the heat sink structure 516b.

In the embodiment illustrated in FIG. 5B, the heat sink structure 516b is vertically positioned within the memory array structure 504b. In additional embodiments, the heat sink structure 516b is vertically positioned within the control logic structure 502b, or is vertically positioned within both the control logic structure 502b and the memory array structure 504b. A horizontal area of the high-power component 510b is at least partially (e.g., substantially) contained within a horizontal area of the heat sink structure 516b.

Referring next to FIG. 5C, the microelectronic device 500c has a high-power component 510c including an ESD SCR. The high-power component 510c includes two electrodes 512c, 514c individually configured as an anode or a cathode. In the embodiment illustrated in FIG. 5C, the electrode 512c is configured as a cathode, and the electrode 514c is configured as an anode. The high-power component 510c also includes two gates 524, 526. The gate 524 is configured as an anode gate 524, and the gate 526 is configured as a cathode gate 526. The electrode 514c and the anode gate 524 are substantially surrounded by an n-well 522. The n-well 522 comprises an n-type doped semiconductor material of the control logic structure 502c.

The electrode 512c and the cathode gate 526 are at least partially surrounded by additional semiconductor material of the control logic structure 502c. The additional semiconductor material of the control logic structure 502c also partially surrounds the n-well 522. The additional semiconductor material of the control logic structure 502c is interposed between the electrodes 512c, 514c and each of the heat sink structures 516c and the contact structures 518c. The additional semiconductor material of the control logic structure 502c is also interposed between the gates 524, 526 and each of the heat sink structures 516c and the contact structures 518c. The additional semiconductor material of the control logic structure 502c is further interposed between the n-well 522 and each of the heat sink structures 516c and the contact structures 518c. The electrodes 512c, 514c, the gates 524, 526, and the n-well 522 are respectively positioned within a horizontal area of the heat sink structure 516c.

In the embodiment illustrated in FIG. 5C, the heat sink structure 516c is vertically positioned within the memory array structure 504c. In other embodiments, the heat sink structure 516c is vertically positioned within the control logic structure 502c, or is vertically positioned within both the control logic structure 502c and the memory array structure 504c. A horizontal area of the high-power component 510c is at least partially (e.g., substantially) contained within a horizontal area of the heat sink structure 516c.

FIG. 5D illustrates a simplified, partial top down view of the microelectronic device 500b of FIG. 5B. In FIG. 5D, the control logic structure 502b and the memory array structure 504b are not shown, so as to more clearly illustrate horizontal arrangements, in both the X-direction and the Y-direction, of the heat sink structure 516b, the contact structures 518b, and the electrodes 512b, 514b of the high-power component 510b. While FIG. 5D illustrates the microelectronic device 500b of FIG. 5B, it will be understood that a similar configuration may be included in the microelectronic devices 500a (FIG. 5A) and 500c (FIG. 5C).

In the embodiment illustrated in FIG. 5D, the heat sink structure 516b includes a mesh structure 528 having lateral bands 530 and longitudinal bands 532. The lateral bands 530 extend in the X-direction and run perpendicular to the electrodes 512b, 514b. The lateral bands 530 individually vertically underlie (e.g., in the Z-direction) and horizontally extend (e.g., in the X-direction) across multiple electrodes 512b, 514b of the high-power component 510b. The longitudinal bands 532 extend in the Y-direction, and run parallel to the electrodes 512b, 514b. Individual longitudinal bands 532 may not horizontally extend, in X-direction, across more than one of the electrodes 512b, 514b.

As shown in FIG. 5D, the lateral bands 530 and the longitudinal bands 532 may define filled openings 534 within the heat sink structure 516b. A relationship between a horizontal area of the heat sink structure 516b and cumulative horizontal areas of the filled openings 534 between the lateral bands 530 and the longitudinal bands 532 may define a total horizontal coverage percentage of the heat sink structure 516b relative to the horizontal area of the microelectronic device 500b occupied by the combination of the heat sink structure 516b and the filled openings 534. For example, in the embodiment illustrated in FIG. 5D, the heat sink structure 516b has a horizontal coverage percentage of about 50 percent (%).

The filled openings 534 may be occupied with semiconductor material of the memory array structure 504b or the control logic structure 502b, depending on where the heat sink structure 516b is vertically positioned. For example, in the embodiment illustrated in FIG. 5B, semiconductor material of the memory array structure 504b occupies the filled openings 534 between the lateral bands 530 and the longitudinal bands 532. In other embodiments, semiconductor material of associated control logic structures (e.g., the control logic structures 302a, 302b previously described with reference to FIGS. 3A and 3C) may occupy filled openings defined by associated heat sink structures (e.g., the heat sink structures 310a, 310c previously described with reference to FIGS. 3A and 3C) vertically positioned within an associated control logic structure (e.g., the control logic structures 302a, 302c previously described with reference to FIGS. 3A and 3C).

The contact structures 518b may form columns vertically extending (e.g., in the Z-direction) from intersection points about the perimeter of the heat sink structure 516b. In the embodiment illustrated in FIG. 5D, a contact structure 518b vertically extends from each intersection between the lateral bands 530 and the perimeter of the heat sink structure 516b and from each intersection between the longitudinal bands 532 and the perimeter of the heat sink structure 516b. As discussed above, the contact structures 518b vertically extend in the Z-direction through the microelectronic device 500b.

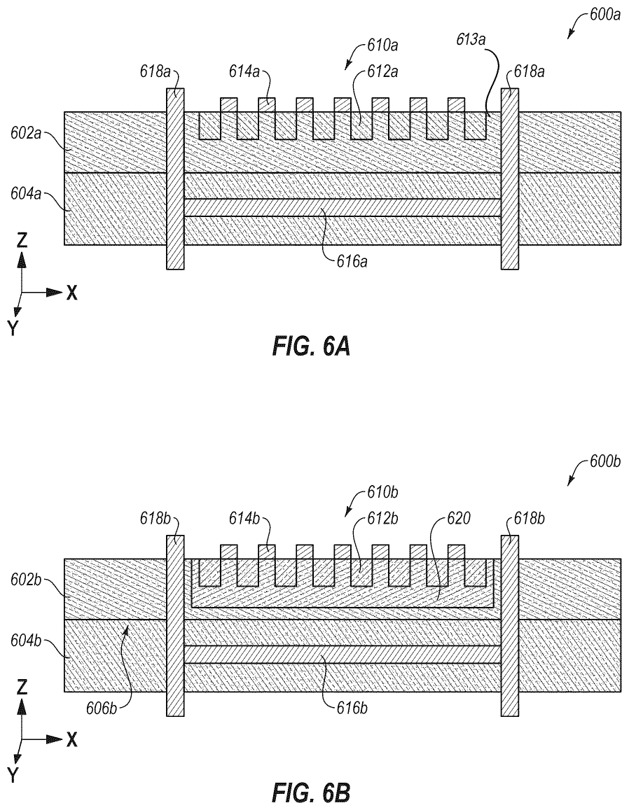

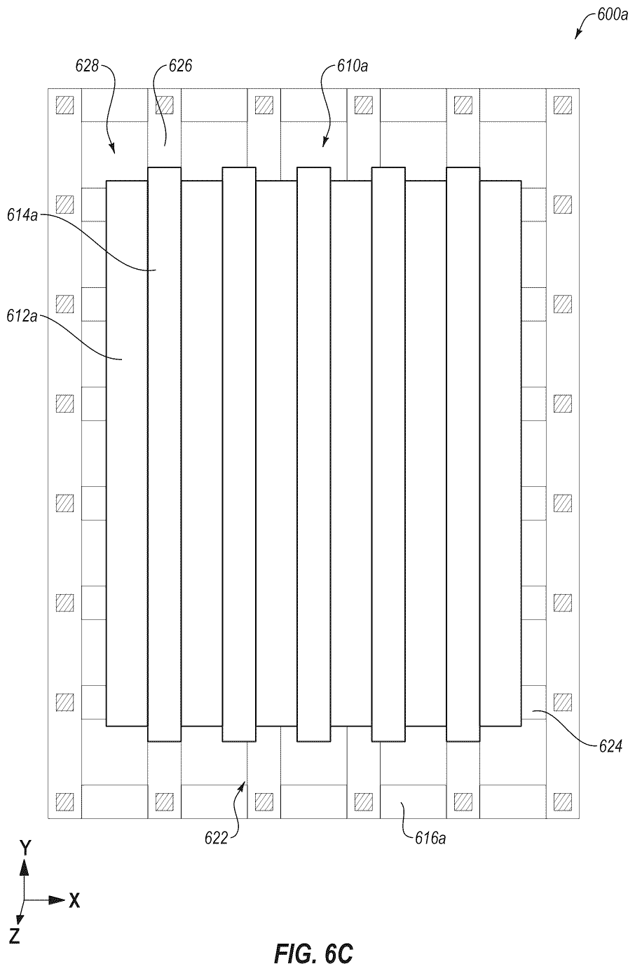

FIGS. 6A and 6B illustrate simplified, partial vertical cross-sections of different microelectronic devices 600a (FIG. 6A), 600b (FIG. 6B), in accordance with embodiments of the disclosure. The microelectronic devices 600a, 600b may have similar configurations to the microelectronic device 400 (FIG. 4), but with different high-power components 610a (FIG. 6A), 610b (FIG. 6B) positioned within a horizontal area of the cup-like structure formed by the combination of the heat sink structures 616a (FIG. 6A), 616b (FIG. 6B) and the contact structures 618a (FIG. 6A), 618b (FIG. 6B). In the embodiments illustrated in FIGS. 6A and 6B, the high-power components 610a (FIG. 6A), 610b (FIG. 6B) may be different types of ESD power clamps. In the embodiment illustrated in FIG. 6A, the high-power component 610a is an ESD NMOS power clamp. In the embodiment illustrated in FIG. 6B, the high-power component 610b is an ESD PMOS power clamp.

Referring to FIG. 6A, the microelectronic device 600a has a high-power component 610a including an ESD NMOS power clamp. The high-power component 610a includes a string of diodes 612a joined together by connectors 614a. The string of diodes 612a is at least partially surrounded by semiconductor material of the control logic structure 602a, such that the semiconductor material of the control logic structure 602a is interposed between each of the diodes 612a in the string of diodes 612a and a heat sink effectively formed by the heat sink structure 616a and the contact structures 618a. In the embodiment illustrated in FIG. 6A, the heat sink structure 616a is vertically positioned within the memory array structure 604a, such that semiconductor material of the memory array structure 604a is interposed between the heat sink structure 616a and the string of diodes 612a.

The entire string of diodes 612a may be horizontally positioned, in the X-direction, between the contact structures 618a horizontally neighboring one another in the X-direction. The semiconductor material of the control logic structure 602a may be horizontally positioned, in the X-direction, between end diodes 612a of the string of diodes 612a and the contact structures 618a. The string of diodes 612a may be at least partially (e.g., substantially) contained within a horizontal area of the heat sink structure 616a.

Referring next to FIG. 6B, the microelectronic device 600b has a high-power component 610b including an ESD PMOS power clamp. The high-power component 610b includes a string of diodes 612b joined together by connectors 614b. The string of diodes 612b may be at least partially surrounded by semiconductor material of the control logic structure 602b, such that the semiconductor material of the control logic structure 602b is interposed between each of the diodes 612b in the string of diodes 612b and a heat sink effectively formed by the heat sink structure 616b and the contact structures 618b. In the embodiment illustrated in FIG. 6B, the heat sink structure 616b is vertically positioned within the memory array structure 604b, such that semiconductor material of the memory array structure 604b is interposed between the heat sink structure 616b and the string of diodes 612b.

The high-power component 610b of the microelectronic device 600b includes an n-well 620 at least partially surrounding the string of diodes 612b. The n-well 620 comprises n-type doped semiconductor material of the control logic structure 602b. The n-well 620 is interposed between the string of diodes 612b and each of the heat sink structures 616b and the contact structures 618b. As illustrated in FIG. 6B, the contact structures 618b are horizontally positioned outside the n-well 620. A horizontal area of the n-well 620 may be at least partially (e.g., substantially) within a horizontal area of the heat sink structure 616b.

As illustrated in FIG. 6B, the n-well 620 of the high-power component 610b is vertically positioned within the control logic structure 602b, such that semiconductor material of the control logic structure 602b is interposed between the n-well 620 and the back side 606b of the control logic structure 602b. Semiconductor material of the control logic structure 602b may be positioned between the n-well 620 and the contact structures 618b in the X-direction.

FIG. 6C illustrates a simplified, partial top down view of the microelectronic device 600a of FIG. 6A. In FIG. 6C, the control logic structure 602a and the memory array structure 604a are not shown so as to more clearly illustrate the horizontal arrangements, in both the X-direction and the Z-direction, of the heat sink structure 616a, the contact structures 618a, the diodes 612a, and the connectors 614a of the high-power component 610a. While FIG. 6C illustrates the microelectronic device 600a of FIG. 6A, it will be understood that a similar configuration may be included in the microelectronic device 600b illustrated in FIG. 6B.

Referring to FIG. 6C, the heat sink structure 616a includes a mesh structure 622 having lateral bands 624 and longitudinal bands 626. The lateral bands 624 extend in the X-direction and run perpendicular to the diodes 612a and connectors 614a. The lateral bands 624 may respectively vertically underlie (e.g., in the Z-direction) and horizontally extend (e.g., in the X-direction) across multiple diodes 612a and connectors 614a of the high-power component 610a. The longitudinal bands 626 may horizontally extend in the Y-direction and may run parallel to the diodes 612a and the connectors 614a. The longitudinal bands 626 may respectively vertically underlie (e.g., in the Z-direction) and horizontally extend (e.g., in the Y-direction) through a horizontal area of the individual diode 612a and/or individual connectors 614a.

The lateral bands 624 and the longitudinal bands 626 of the mesh structure 622 define filled openings 628. A relationship between a horizontal area of the heat sink structure 616a and cumulative horizontal areas of the filled openings 628 between the lateral bands 624 and the longitudinal bands 626 may define a total horizontal coverage percentage of the heat sink structure 616a relative to the horizontal area of the microelectronic device 600a occupied by the combination of the heat sink structure 616a and the filled openings 628. For example, in the embodiment illustrated in FIG. 6C, the heat sink structure 616a has a horizontal coverage percentage of about 50 percent (%).

The filled openings 628 may be occupied by semiconductor material of the memory array structure 604a or the control logic structure 602a, depending on where the heat sink structure 616a is vertically positioned. For example, in the embodiment illustrated in FIG. 6A, the semiconductor material of the memory array structure 604a occupies the filled openings 628 between the lateral bands 624 and the longitudinal bands 626. In other embodiments, semiconductor material of an associated control logic structure (e.g., the control logic structures 302a, 302b previously described with reference to FIGS. 3A and 3C) may occupy filled openings defined by associated heat sink structures (e.g., the heat sink structures 310a, 310c previously described with reference to FIGS. 3A and 3C) vertically positioned within an associated control logic structure (e.g., the control logic structures 302a, 302c previously described with reference to FIGS. 3A and 3C).

The contact structures 618a may form columns vertically extending (e.g., in the Z-direction) from intersection points about the perimeter of the heat sink structure 616a. In the embodiment illustrated in FIG. 6C, a contact structure 618a vertically extends from each intersection between the lateral bands 624 and the perimeter of the heat sink structure 616a, and from each intersection between the longitudinal bands 626 and the perimeter of the heat sink structure 616a. As discussed above, the contact structures 618a respectively vertically extend in the Z-direction through the microelectronic device 600a.

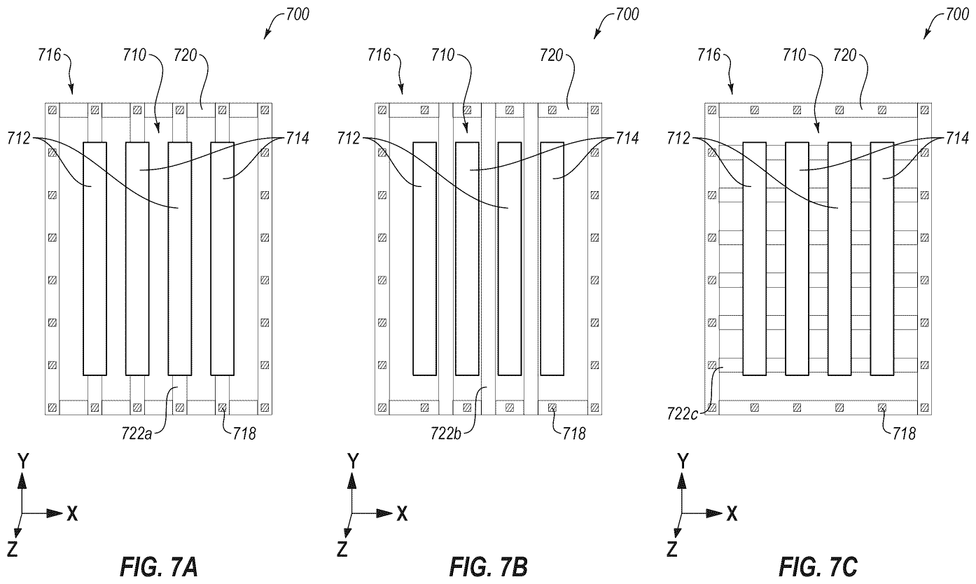

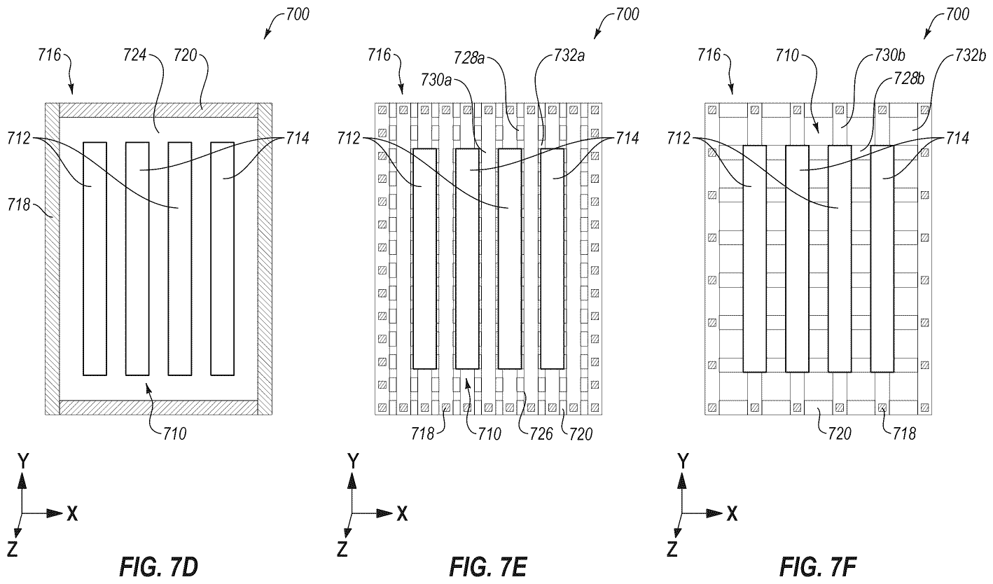

FIGS. 7A-7F illustrate simplified, partial top-down views of a different configurations for microelectronic device, in accordance with embodiments of the disclosure. FIGS. 7A-7F shown different arrangements of a heat sink structure 716 within the microelectronic device 700. In each of FIGS. 7A-7F, the microelectronic device 700 is illustrated without a control logic structure or memory logic structure to more clearly illustrate the lateral arrangements, in both the X-direction and the Y-direction, of the heat sink structure 716, the contact structures 718, and the electrodes 712, 714 of the high-power component 710. While FIGS. 7A-7F illustrate a microelectronic device 700 including a high-power component 710 including the electrodes 712 and 714, it will be understood that similar features can be included in any of the microelectronic devices 100, 300a, 300b, 300c, 400, 500a, 500b, 500c, 600a, 600b previously described herein.

Referring to FIG. 7A, the heat sink structure 716 is positioned vertically beneath a high-power component 710. The heat sink structure 716 includes a perimeter structure 720 extending around the high-power component 710, such that the high-power component 710 is horizontally surrounded by the perimeter structure 720 both in the X-direction and in the Y-direction. The contact structures 718 extend vertically in the Z-direction from several points along the perimeter structure 720. The heat sink structure 716 also includes bands 722a that horizontally extend in parallel in the Y-direction between horizontal ends of the perimeter structure 720. The bands 722a vertically underlie the high-power component 710 in the Z-direction.

The bands 722a horizontally extend parallel to the electrodes 712, 714. In the embodiment illustrated in FIG. 7A, the bands 722a have a 0% horizontal offset relative to the electrodes 712, 714 in the X-direction, such that the bands 722a are substantially horizontally aligned with the electrodes 712, 714 in the X-direction. In embodiments where the offset between the bands 722a and the electrodes 712, 714 is 0%, such as the embodiment of FIG. 7A, a distance between the bands 722a and the electrodes 712, 714 is the vertical distance 422 (FIG. 4). In some embodiments, the bands 722a are horizontally offset from the electrodes 712, 714 in the X-direction, so as to accommodate other structures in the microelectronic device 700 or to resolve other design-specific requirements. As the horizontal offset between the bands 722a and the electrodes 712, 714 in the X-direction increases, the total distance between the bands 722a and the electrodes 712, 714 also increases.

Referring next to FIG. 7B, the heat sink structure 716 includes bands 722b having a 50% horizontal offset relative to the electrodes 712, 714 in the X-direction. The bands 722b horizontal extend in parallel in the Y-direction between the horizontal ends of the perimeter structure 720, similar to the bands 722a previously described with reference to FIG. 7A. The bands 722b also horizontally extend parallel to the electrodes 712, 714, similar to the bands 722a previously described with reference to FIG. 7A. However, due to the 50% horizontal offset, the bands 722b are not substantially horizontally aligned with the electrodes 712, 714 in the X-direction. Rather, the bands 722b have substantially no horizontal overlap with the electrodes 712, 714 in the X-direction. The bands 722b in FIG. 7B are positioned within horizontal areas of gaps between the electrodes 712, 714. The total distance between the bands 722b and the electrodes 712, 714 may be found in the following formula:

$$D = \sqrt{{V}^{2} + {L}^{2}} ,$$

where D is the total distance between the bands 722b and the electrodes 712, 714; V is the vertical offset between the bands 722b and the electrodes 712, 714; and L is the horizontal offset between the bands 722b and the electrodes 712, 714. In embodiments wherein a horizontal offset in the X-direction is utilized to accommodate other features, the vertical offset in the Z-direction may be decreased to maintain an effective total distance between the bands 722b and the electrodes 712, 714.

Referring to FIG. 3C, in some embodiments, bands 722c horizontally extend in parallel in the X-direction between ends of the perimeter structure 720. The bands 722c illustrated in FIG. 7C horizontally extend substantially perpendicular to the electrodes 712, 714. The bands 722c pass beneath multiple of the electrodes 712, 714 in the X-direction, and respectively are not substantially aligned with an individual one of the electrodes 712, 714 in the X-direction. In other embodiments, the bands 722c may horizontally extend at an angle (e.g., an acute angle, an obtuse angle) relative to the electrodes 712, 714. In the embodiment illustrated in FIG. 7C, the bands 722c horizontally extend at a 90° angle relative to the electrodes 712, 714. In other embodiments, the bands 722c may extend at an angle between 90° and 1°, relative to the electrodes 712, 714, such as at a 45° angle relative to the electrodes 712, 714. As the angle between the bands 722c and the electrodes 712, 714 changes, the effective coverage of the heat sink structure 716 may also change. For example, the bands 722a of FIG. 7A that horizontally extend at an angle of 0° relative to the electrodes 712, 714 and that have substantially 0% horizontal offset relative to the electrodes 712, 714 may have a greater effective coverage than the bands 722c of FIG. 7C that horizontally extend at an angle of 90° relative to the electrodes 712, 714.

Another aspect of the heat sink structure 716 that may influence effective coverage is a coverage percentage, which is the percentage of the horizontal area having horizontal boundaries defined by the perimeter structure 720 covered by the heat sink structure 716. In the embodiments illustrated in FIGS. 7A-7C, the horizontal area defined by the spaces between the bands 722a, 722b, 722c is larger than the horizontal area defined by the bands 722a, 722b, 722c. Therefore, the coverage percentage is less than about 50%, such as within a range from about 20% to about 50%. FIGS. 7D-7E illustrate configurations having different coverage percentages that are equal to or greater than about 50%. Thus, different embodiments of the heat sink structure 716 may define a coverage percentage within a range from about 20% to about 100%, such as within a range from about 25% to about 100%, from about 50% to about 100%, or from about 50% to about 75%.

Referring to FIG. 7D, the heat sink structure 716 includes a plate 724 providing 100% coverage of the high-power component 710. The plate 724 fully covers the horizontal area of the high-power component 710, including both the total horizontal area of the electrodes 712, 714 and the total horizontal area of the gaps between the electrodes 712, 714. As illustrated in FIG. 7D, the high-power component 710 is substantially contained within the horizontal area of the plate 724.

The contact structures 718 extend vertically from the perimeter of the plate 724. In the embodiment illustrated in FIG. 7D, the contact structures 718 are slot structures. Slot structures are plate structures or wall structures having an elongated rectangular horizonal cross-section and extending vertically from the plate 724. In additional embodiments, one or more of the contact structures 718 are column structures (e.g., circular column structures, square column structures) vertically extending from the perimeter region of the plate 724. For example, one or more sides of the plate 724 may include contact structures 718 that are columns, and other sides of the plate 724 may include contact structures that are slot structures. In another example, the contact structures 718 may include multiple slot structures with gaps horizontally between the horizontally neighboring contact structures 718.

Referring next to FIG. 7E, the heat sink structure 716 includes a mesh structure 726 formed from first bands 728a and second bands 730a. The first bands 728a and the second bands 730a may define openings 732a in the mesh structure 726. The coverage percentage is the ratio of the total horizontal area within the perimeter structure 720 of the heat sink structure 716 to the total horizontal area of the mesh structure 726 of the heat sink structure 716. In the embodiment illustrated in FIG. 7E, the mesh structure 726 covers about 75% of the horizontal area bounded by the perimeter structure 720 of the heat sink structure 716.

Referring to FIG. 7F, the heat sink structure 716 includes a mesh structure 726 formed from first bands 728b and second bands 730b. The first bands 728b and the second bands 730b define openings 732b in the mesh structure 726. In the embodiment illustrated in FIG. 7F, the mesh structure 726 covers about 50% of the horizontal area bounded by the perimeter structure 720 of the heat sink structure 716.

In the embodiments illustrated in FIGS. 7E and 7F, the difference in the coverage percentages is created by a different number of first bands 728a (FIG. 7E), 728b (FIG. 7F) and second bands 730a (FIG. 7E), 730b (FIG. 7F). In the embodiment illustrated in FIG. 7E, there are a greater number of first bands 728a and second bands 730a than the number of first bands 728b and second bands 730b in the embodiment of FIG. 7F. The greater number of first bands 728a and second bands 730a result in a greater amount of coverage. In other embodiments, horizontal dimensions of the first bands 728a (FIG. 7E), 728b (FIG. 7F) and the second bands 730a (FIG. 7E), 730b (FIG. 7F) may be changed between embodiments to create different coverages. For example, two heat sink structures 716 may have a same number of first bands 728a (FIG. 7E), 728b (FIG. 7F) and/or second bands 730a (FIG. 7E), 730b (FIG. 7F), with one of the heat sink structures 716 having a greater coverage percentage because of the differences in the horizontal widths in the Y-direction of the first bands 728a (FIG. 7E) and the first bands 728b (FIG. 7F) relative to one another, and/or differences in the horizontal widths in the X-direction the second bands 730a (FIG. 7E) and the second bands 730b (FIG. 7F) relative to one another.

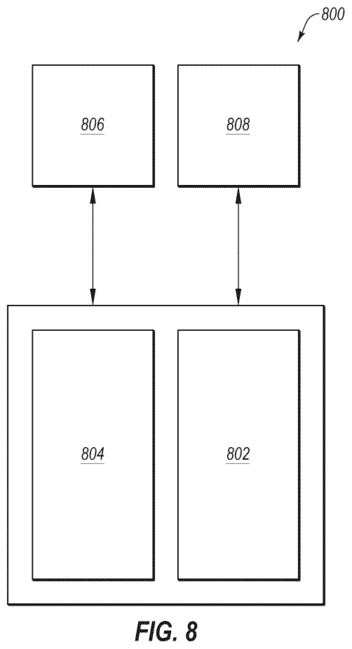

Microelectronic devices (e.g., the microelectronic devices 100, 300a, 300b, 300c, 400, 500a, 500b, 500c, 600a, 600b, and 700) according to embodiments of the disclosure may be included in embodiments of electronic systems of the disclosure. For example, FIG. 8 is a block diagram of an electronic system 800, in accordance with embodiments of the disclosure. The electronic system 800 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 800 includes at least one memory device 802. The memory device 802 may include, for example, an embodiment of a semiconductor device package including one or more of the microelectronic devices previously described herein (e.g., the microelectronic devices 100, 300a, 300b, 300c, 400, 500a, 500b, 500c, 600a, 600b, and 700 previously described with reference to FIGS. 1 through 7F).

The electronic system 800 may further include at least one electronic signal processor device 804 (often referred to as a “microprocessor”). The electronic signal processor device 804 may, optionally, include an embodiment of one or more of a microelectronic device and a microelectronic device structure previously described herein. The electronic system 800 may further include one or more input devices 806 for inputting information into the electronic system 800 by a user, such as, for example, a mouse or other pointing device, a keyboard, a touchpad, a button, or a control panel. The electronic system 800 may further include one or more output devices 808 for outputting information (e.g., visual or audio output) to a user such as, for example, a monitor, a display, a printer, an audio output jack, a speaker, etc. In some embodiments, the input device 806 and the output device 808 may comprise a single touchscreen device that can be used both to input information to the electronic system 800 and to output visual information to a user. The input device 806 and the output device 808 may communicate electrically with one or more of the memory device 802 and the electronic signal processor device 804.

Thus, embodiments of the disclosure include a microelectronic device. The microelectronic device includes a control logic structure including a high-power component. The microelectronic device also includes a memory array structure vertically offset from and attached to the control logic structure, the memory array structure comprising an array of memory cells. The microelectronic device further includes a heat sink structure vertically underlying and horizontally overlapping the high-power component, the heat sink structure comprising a material having higher thermal conductivity than semiconductor material of the control logic structure.

Another embodiment of the disclosure includes an electronic system. The electronic system includes an input device, an output device, a processor device operably coupled to the input device and the output device, and a memory device operably coupled to the processor device. The memory device includes a control logic structure including a high-power component. The memory device also includes a memory array structure vertically underlying and bonded to control logic structure. The memory device further includes a heat sink structure vertically interposed between the high-power component of the control logic structure and a memory array of the memory array structure, the heat sink structure at least partially within a horizontal area of the high-power component of the control logic structure. The memory device also includes contact structures extending vertically through the control logic structure and the memory array structure, the contact structures respectively in physical contact with a perimeter section of the heat sink structure.

Other embodiments of the disclosure include a memory device. The memory device includes a control logic structure including an electrostatic discharge (ESD) protection device. The memory device further includes a memory array structure vertical offset from and dielectric-to-dielectric bonded coupled to the control logic structure, the memory array structure comprising non-volatile memory cells. The memory device also includes a heat sink structure within a horizontal area of the ESD protection device of the control logic structure and vertically interposed between the ESD protection device of the control logic structure and at least a portion of the memory array structure, the heat sink structure comprising bands horizontally extending in parallel in a first direction ad horizontal overlapping electrodes of the ESD protection device in a second direction orthogonal to the second direction.

The structures and devices of the disclosure may facilitate enhanced heat dissipation for high-power components relative to conventional structures and devices. Dissipating the heat from the high-power components may facilitate reductions in volumes of semiconductor material employed in devices of the disclosure relative to conventional devices. Reducing the volume of semiconductor material may facilitate the production of relatively thin devices and/or the inclusion of higher power components and/or a greater number of high-power components. In addition, reductions in space requirements and the inclusion of more high-power components may facilitate reductions in space requirements within the associated devices and/or the inclusion of more functional components with the associated devices.

The embodiments of the disclosure described above and illustrated in the accompanying drawing figures do not limit the scope of the invention, since these embodiments are merely examples of embodiments of the invention, which are defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device comprising:
a control logic structure including a high-power component;
a memory array structure vertically offset from and attached to the control logic structure, the memory array structure comprising an array of memory cells; and
a heat sink structure vertically underlying and horizontally overlapping the high-power component, the heat sink structure comprising a material having higher thermal conductivity than semiconductor material of the control logic structure.

2. The microelectronic device of claim 1, wherein the heat sink structure is vertically positioned in the memory array structure.

3. The microelectronic device of claim 1, wherein the memory array structure is attached to the control logic structure through dielectric-to-dielectric bonding.

4. The microelectronic device of claim 1, wherein the heat sink structure comprises a mesh structure including:
first bands horizontally extending in parallel in a first direction; and
second bands intersecting the first bands and horizontally extending in parallel in a second direction orthogonal to the first direction.

5. The microelectronic device of claim 4, wherein the first bands and the second bands define openings in the mesh structure.

6. The microelectronic device of claim 1, wherein the heat sink structure horizontally covers from about 50% to about 100% of the high-power component.

7. The microelectronic device of claim 1, wherein the high-power component comprises an electrostatic discharge (ESD) component.

8. The microelectronic device of claim 1, wherein the array of memory cells of the memory array structure comprises an array of non-volatile memory cells.

9. An electronic system, comprising:
an input device;
an output device;
a processor device operably coupled to the input device and the output device; and
a memory device operably coupled to the processor device and comprising:
a control logic structure including a high-power component;
a memory array structure vertically underlying and bonded to control logic structure;
a heat sink structure vertically interposed between the high-power component of the control logic structure and a memory array of the memory array structure, the heat sink structure at least partially within a horizontal area of the high-power component of the control logic structure; and
contact structures extending vertically through the control logic structure and the memory array structure, the contact structures respectively in physical contact with a perimeter section of the heat sink structure.

10. The electronic system of claim 9, wherein the horizontal area of the high-power component is within a horizontal area of the heat sink structure.

11. The electronic system of claim 10, wherein the horizontal area of the heat sink structure is defined by outer horizontal boundaries of the perimeter section of the heat sink structure.

12. The electronic system of claim 9, wherein the heat sink structure is at least partially vertically positioned within the memory array structure.

13. The electronic system of claim 9, wherein the heat sink structure is at least partially vertically positioned within the control logic structure.

14. The electronic system of claim 9, wherein:
the high-power component comprises electrodes horizontally extending in parallel in a first direction; and
the heat sink structure comprises bands horizontally extending in parallel in the first direction.

15. The electronic system of claim 14, wherein the bands of the heat sink structure horizontally overlap the electrodes of the high-power component in a second direction orthogonal to the first direction.

16. The electronic system of claim 15, wherein horizontal centerlines of the bands of the heat sink structure are substantially aligned with horizontal centerlines of the electrodes in a second direction.

17. The electronic system of claim 14, wherein the bands of the heat sink structure are substantially horizontally offset from the electrodes of the high-power component in a second direction orthogonal to the first direction.

18. The electronic system of claim 9, wherein:
the high-power component comprises electrodes horizontally extending in parallel in a first direction; and
the heat sink structure comprises bands horizontally extending in parallel in a second direction angled relative to the first direction.

19. The electronic system of claim 18, wherein the second direction is substantially orthogonal to the first direction.

20. A memory device, comprising:
a control logic structure including an electrostatic discharge (ESD) protection device;
a memory array structure vertical offset from and dielectric-to-dielectric bonded coupled to the control logic structure, the memory array structure comprising non-volatile memory cells; and
a heat sink structure within a horizontal area of the ESD protection device of the control logic structure and vertically interposed between the ESD protection device of the control logic structure and at least a portion of the memory array structure, the heat sink structure comprising bands horizontally extending in parallel in a first direction ad horizontal overlapping electrodes of the ESD protection device in a second direction orthogonal to the second direction.
